(19) United States
(12) Patent Application Publication
(10) Pub. No.: US 2024/0074291 A1
(43) Pub. Date: Feb. 29, 2024

(54) FLEXIBLE DISPLAY PANEL AND MANUFACTURING METHOD THEREOF

(71) Applicant: Shenzhen China Star Optoelectronics Semiconductor Display Technology Co., Ltd., Shenzhen, Guangdong (CN)

(72) Inventors: Weiran CAO, Shenzhen, Guangdong (CN); Shijian QIN, Shenzhen, Guangdong (CN); Hui HUANG, Shenzhen, Guangdong (CN); Min ZHANG, Shenzhen, Guangdong (CN)

(73) Assignee: Shenzhen China Star Optoelectronics Semiconductor Display Technology Co., Ltd., Shenzhen, Guangdong (CN)

(21) Appl. No.: 17/764,998

(22) PCT Filed: Mar. 2, 2022
(86) PCT No.: PCT/CN2022/078766

§ 371 Date: Mar. 30, 2022

(30) Foreign Application Priority Data
Feb. 24, 2022 (CN) 202210170436.X

(51) Int. Cl. H10K 59/80; H10K 71/00

(52) U.S. Cl. CPC H10K 59/874; H10K 59/873; H10K 71/861; H10K 2102/311

(57) ABSTRACT

Embodiments of the present disclosure provide a flexible display panel and a manufacturing method thereof, wherein the flexible display panel includes: an array substrate; an organic light emitting layer disposed on the array substrate; a dam disposed on the array substrate and disposed to surround the organic light emitting layer; and an encapsulation layer covering the organic light emitting layer and the dam, wherein the dam comprises a first side surface close to the organic light emitting layer, and a second side surface away from the organic light emitting layer, and the second side surface is disposed with at least one of a groove, a stepped structure, or a sharp corner structure.

### TECHNICAL FIELD

The present disclosure relates to a display technology field, and more particularly to a flexible display panel and a manufacturing method thereof.

### BACKGROUND

In an organic light-emitting diode (OLED) display device, an organic layer and other devices are susceptible to corrosion by oxygen and water, thereby reducing their lifespan. Therefore, it is necessary to encapsulate an AMOLED display panel. As for flexible displays, a thin film encapsulation (TFE) is one of most-commonly used encapsulating methods. In current TFE encapsulating technologies, in order to avoid a case where a boundary of a thin film formed when ink is leveled on a substrate is irregular or extends beyond the boundary of the substrate, a dam is usually provided at a position corresponding to an ink print boundary on the substrate.

### Technical Problems

However, in the related art, the ink often flows beyond the dam, which reduces a lifespan of the display panel.

### Technical Solutions

Embodiments of the present disclosure provide a flexible display panel and a manufacturing method thereof, which can solve a problem that ink flows beyond a dam in a current display panel.

Embodiments of the present disclosure provide a flexible display panel, the flexible display panel including:
An array substrate;
An organic light emitting layer, wherein the organic light emitting layer is disposed on the array substrate;
A dam, wherein the dam is disposed on the array substrate and disposed to surround the organic light emitting layer; and
An encapsulation layer, wherein the encapsulation layer covers the organic light emitting layer and the dam, and the encapsulation layer includes ink;
Wherein the dam includes a top surface away from the array substrate, a first side surface close to the organic light emitting layer, and a second side surface away from the organic light emitting layer, and the second side surface is disposed with at least one of a groove, a stepped structure, or a sharp corner structure.

An embodiment of the present disclosure further provides a manufacturing method of a flexible display panel, the manufacturing method including:
Providing an array substrate;
Disposing an organic light emitting layer on the array substrate;
Disposing a dam to surround the organic light emitting layer on the array substrate, the dam including a top surface and side surfaces, wherein the top surface is disposed on a side of the dam away from the array substrate, the side surfaces including a first side surface close to the organic light emitting layer and a second side surface away from the organic light emitting layer; and the second side surface is disposed with at least one of a groove, a stepped structure or a sharp corner structure; and
Disposing an encapsulation layer on the organic light emitting layer to cover the organic light emitting layer and the dam, wherein the encapsulation layer includes ink.

### Beneficial Effects

A flexible display panel provided in embodiments of the present disclosure includes an array substrate, an organic light emitting layer, an encapsulation layer, and a dam. The dam is disposed on the array substrate, and a second side of the dam is disposed with at least one of a groove, a stepped structure, or a sharp corner structure. A contact area between the dam and ink in the encapsulation layer may be increased by the groove, the stepped structure, or the sharp corner structure, and then surface tension of the ink in the encapsulation layer is increased to prevent the ink from flowing beyond the dam. In addition, when the flexible display panel is bent, the groove, the stepped structure or the sharp-angle structure disposed at the dam may avoid the case that the flexible display panel is broken due to stress concentration, thereby increasing the lifespan of the flexible display panel.

### BRIEF DESCRIPTION OF THE DRAWINGS

FIG. 1 is a structural schematic view of a flexible display panel according to an embodiment of the present disclosure.

FIG. 2 is a first structural schematic view of a dam in the flexible display panel shown in FIG. 1.

FIG. 3 is a second structural schematic view of a dam in the flexible display panel shown in FIG. 1.

FIG. 4 is a third structural schematic view of a dam in the flexible display panel shown in FIG. 1.

FIG. 5 is a fourth structural schematic view of a dam in the flexible display panel shown in FIG. 1.

FIG. 6 is a fifth structural schematic view of a dam in the flexible display panel shown in FIG. 1.

FIG. 7 is a sixth structural schematic view of a dam in the flexible display panel shown in FIG. 1.

FIG. 8 is a seventh structural schematic view of a dam in the flexible display panel shown in FIG. 1.

FIG. 9 is an eighth structural schematic view of a dam in the flexible display panel shown in FIG. 1.

FIG. 10 is a first schematic flowchart of a manufacturing method of the flexible display panel according to an embodiment of the present disclosure.

FIG. 11 is a schematic flowchart of manufacturing a dam in the manufacturing method described in FIG. 10.

FIG. 12 is a second schematic flowchart of a manufacturing method of a flexible display panel according to an embodiment of the present disclosure.

FIG. 13 is a third schematic flowchart of a manufacturing method of a flexible display panel according to an embodiment of the present disclosure.

### EMBODIMENT OF THE PRESENT DISCLOSURE

Technical solutions in embodiments of the present disclosure will be clearly and completely described below with reference to the accompanying drawings in the embodiments of the present disclosure. Apparently, described embodiments are only a part of the embodiments of the present disclosure, but not all of the embodiments. Based on the embodiments in the present disclosure, all other embodiments obtained without creative work by those skilled in the art fall within the protection scope of the present disclosure.

In the description of the present disclosure, it should be understood that orientations or position relationships indicated by the terms “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, and “counter-clockwise” are based on orientations or position relationships illustrated in the drawings. The terms are used to facilitate and simplify the description of the present disclosure, rather than indicate or imply that the devices or elements referred to herein are required to have specific orientations or be constructed or operate in the specific orientations. Accordingly, the terms should not be construed as limiting the present disclosure. In addition, the term “first”, “second” are for illustrative purposes only and are not to be construed as indicating or imposing a relative importance or implicitly indicating the number of technical features indicated. Thus, a feature that limited by “first”, “second” may expressly or implicitly include one or more of the features. In the description of the present disclosure, the meaning of “plural” is two or more, unless otherwise specifically defined.

Organic light emitting diodes (OLEDs) have been increasingly used in various display fields due to characteristics such as self-emission, wide viewing angles, rapid response speed, being able to be fabricated on flexible substrates, and the like. A display panel typically uses a thin film encapsulation structure to achieve sealing of a display area. The thin film encapsulation structure has a low cost and a good sealing effect, and is widely used in OLED display panels.

However, in the prior art, a dam and a pixel definition layer (PDL) are generally formed by an exposure process by using a primary mask. In an actual production, thicknesses of edges of an organic film layer are much less than a thickness of a center of the organic film layer, resulting in ink not effectively coating devices. The ink often flows beyond the dam, which reduces the lifespan of the OLED.

Therefore, in order to solve the above problems, the present disclosure provides a display panel and a method of manufacturing the display panel. The present disclosure will be further described with reference to the accompanying drawings and embodiments.

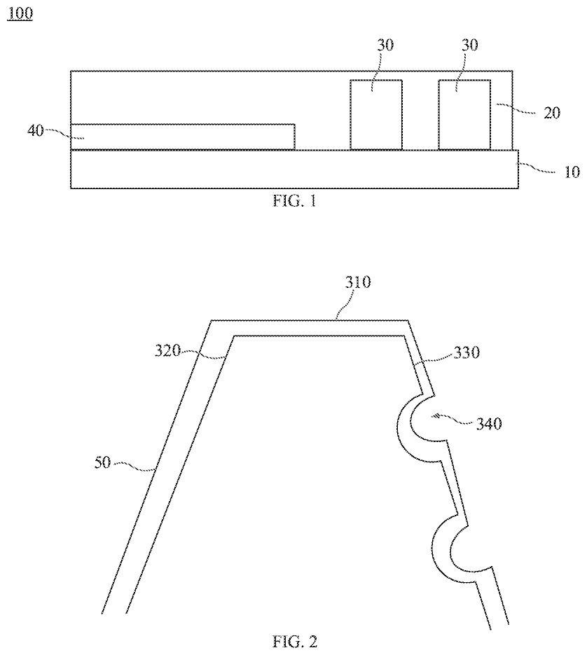

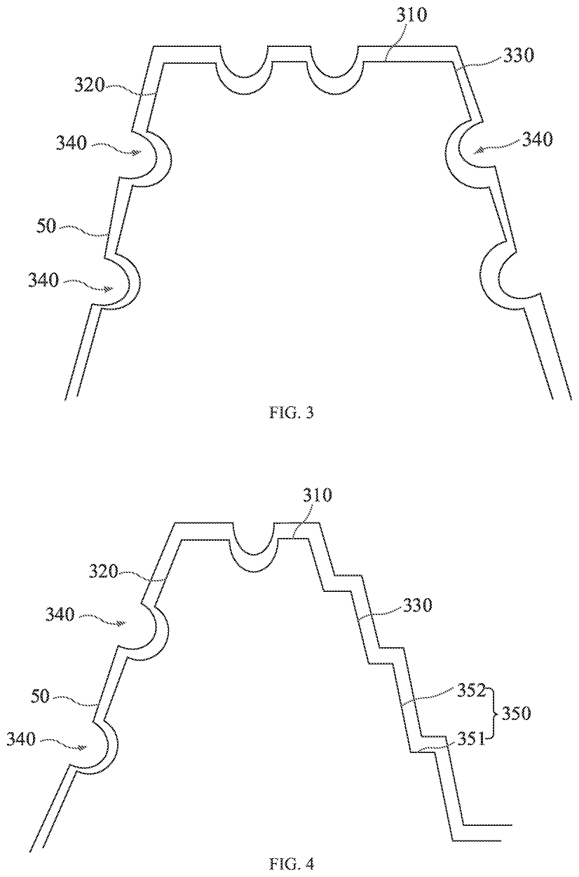

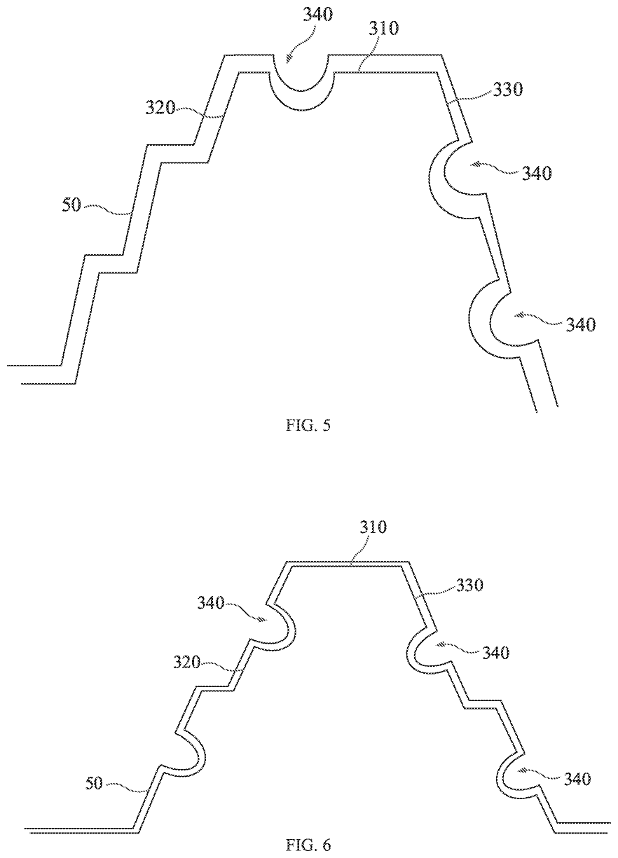

Referring to FIGS. 1-4, FIG. 1 is a structural schematic view of a flexible display panel according to an embodiment of the present disclosure, FIG. 2 is a first structural schematic view of a dam in the flexible display panel shown in FIG. 1, FIG. 3 is a second structural schematic view of the dam in the flexible display panel shown in FIG. 1, and FIG. 4 is a third structural schematic view of the dam in the flexible display panel shown in FIG. 1. A flexible display panel 100 is provided in an embodiment of the present disclosure. The flexible display panel 100 includes a display area and a non-display area disposed to surround the display area. The flexible display panel 100 includes an array substrate 10, an organic light emitting layer 40, an encapsulation layer 20, and a dam 30. The organic light emitting layer 40 is disposed on the array substrate 10 in the display area. The encapsulation layer 20 covers the organic light emitting layer 40 and the dam 30, and the encapsulation layer 20 includes ink. The dam 30 is disposed on the array substrate 10, the dam 30 is disposed to surround the organic light emitting layer 40, and the dam 30 includes a top surface 310 and side surfaces. The top surface 310 is disposed on a side of the dam 30 away from the array substrate 10. The side surfaces include a first side surface 320 close to the organic light emitting layer 40 and a second side surface 330 away from the organic light emitting layer 40. The second side surface 330 is disposed with at least one of a groove(s) 340, a stepped structure 350, or a sharp corner structure(s) 360. Through the groove(s) 340, the stepped structure 350, or the sharp corner structure(s) 360, it is possible to increase a contact area between the dam 30 and the ink in the encapsulation layer 20, thereby increasing surface tension of the ink in the encapsulation layer 20 to prevent the ink from flowing beyond the dam 30. In addition, the ink in the encapsulation layer 20 may also be accommodated in the grooves 340 to further prevent the ink from flowing beyond the dam 30. In addition, when the flexible display panel 100 is bent, the groove(s) 340, the stepped structure 350, or the sharp corner structure(s) 360 disposed in the dam 30 can avoid a case where the flexible display panel 100 is broken due to stress concentration, thereby increasing the lifespan of the flexible display panel 100.

Please continue to refer to FIG. 2, the grooves 340 is defined on the second side surface 330. By defining the grooves 340 at the second side surface 330, the contact area between the ink in the encapsulation layer 20 and the dam 30 may be increased, and the grooves 340 may accommodate the ink to further prevent the ink from flowing beyond the dam 30. In addition, when the flexible display panel 100 is bent, the grooves 340 disposed at the dam 30 can avoid the case where the flexible display panel 100 is broken due to the stress concentration, thereby increasing the lifespan of the flexible display panel 100. In some embodiments, at least one of the top surface 310 and the first side surface 320 is disposed with the grooves 340. By way of example, in some embodiments, both the top surface 310 and the first side surface 320 of the dam 30 are disposed with the grooves 340, and the second side surface 330 may be disposed with the grooves 340, the stepped structure 350, or the sharp corner structures 360. In some embodiments, the top surface 310 and the second side surface 330 of the dam 30 are disposed with the grooves 340, and the first side surface 320 may be disposed with the grooves 340 or the stepped structure 350. In some embodiments, the first side surface 320 and the second side surface 330 of the dam 30 are disposed with the grooves 340, and the top surface 310 may be disposed with grooves 340 or may not be disposed with grooves 340. In some other embodiments, the top surface 310, the first side surface 320, and the second side surface 330 of the dam 30 all are disposed with the grooves 340, as shown in FIG. 3. It may be understood that a position of the grooves 340 defined at the dam 30 may be designed according to actual conditions and is not specifically limited here.

The cross-sectional shape of the grooves 340 may be one of a rectangular shape, a trapezoidal shape, a triangular shape, a V-shaped shape, an arc shape, or a semi-elliptical shape. It may be understood that a number, size, and shape of the grooves 340 defined at the top surface 310 and at the side surfaces may be same or may be different. The specific case of disposing the grooves 340 is designed according to actual conditions and is not specifically limited here.

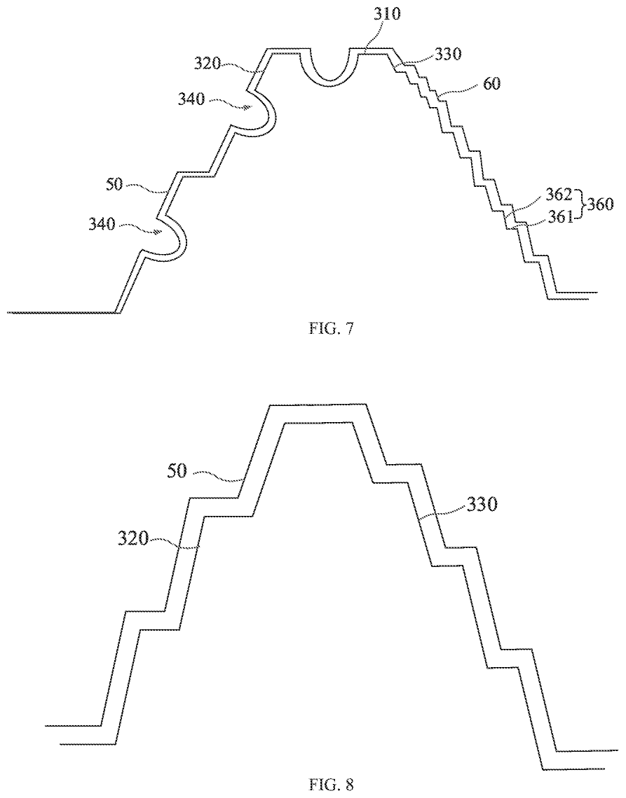

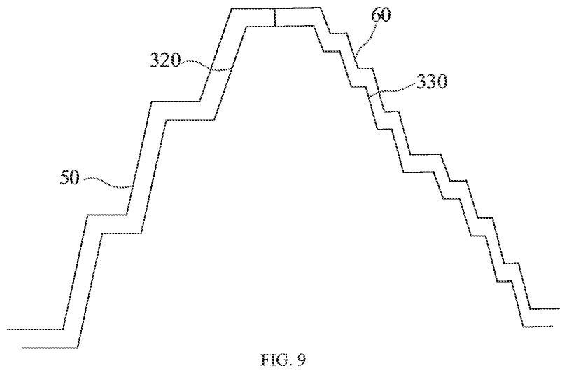

Please continue referring to FIGS. 4-6, FIG. 5 is a fourth structural schematic view of the dam in the flexible display panel shown in FIG. 1, and FIG. 6 is a fifth structural schematic view of the dam in the flexible display panel shown in FIG. 1. At least one of the first side surface 320 and the second side surface 330 of the dam 30 is disposed as the stepped structure 350. By way of example, in some embodiments, the top surface 310 and the first side surface 320 of the dam 30 both are disposed with the grooves 340, and the second side surface 330 is disposed as the stepped structure 350, as shown in FIG. 4. In some embodiments, the top surface 310 and the second side surface 330 of the dam 30 both are disposed with the grooves 340, and the first side surface 320 is disposed as the stepped structure 350, as shown in FIG. 5. It should be noted that the second side surface 330 may be the stepped structure 350, may be the grooves 340, or may be the stepped structure 350 and be disposed with the grooves 340. In some embodiments, the first side surface 320 and the second side surface 330 of the dam 30 are disposed with the grooves 340, and the first side surface 320 and the second side surface 330 are the stepped structure 350, that is, the grooves 340 is disposed on the stepped structure 350, as shown in FIG. 6. It may be understood that the arrangement of the dam 30 is not limited to the above examples, and other arrangements may be combined and arranged as required, and details are not described here. By disposing the side surfaces as the stepped structure 350, the contact area between the ink and the dam 30 can be effectively increased, the surface tension of the ink can be increased, and the ink can be effectively prevented from flowing beyond the dam 30.

The stepped structure 350 includes a first plane 351 and a second plane 352 intersected with each other, the first plane 351 being parallel to the array substrate 10, an included angle between the second plane 352 and the first plane 351 being greater than 0 degrees and less than 180 degrees. By way of example, the included angle between the second plane 352 and the first plane 351 may be 90 degrees, 120 degrees, 135 degrees, 165 degrees, or the like.

Please continue referring to FIG. 7, FIG. 7 is a sixth structural schematic view of the dam in the flexible display panel shown in FIG. 1. In some embodiments, the second side surface 330 of the dam 30 is disposed with two or more sharp corner structures 360. By way of example, the grooves 340 are defined in the top surface 310 and the first side surface 320 of the dam 30, and the second side surface 330 is disposed with two or more sharp corner structures 360. Alternatively, the grooves 340 are defined in the top surface 310 and the first side surface 320 of the dam 30, the first side surface 320 is disposed as the stepped structure 350, and the second side surface 330 is disposed with two or more sharp corner structures 360. Alternatively, the grooves 340 are disposed in the top surface 310 and the second side surface 330 of the dam 30, and the first side surface 320 is disposed as the stepped structure 350, that is, the grooves 340 is defined on the stepped structure 350 of the first side surface 320, and the second side surface 330 is disposed with two or more sharp corner structures 360. A density of the sharp corner structures 360 disposed on the second side surface 330 is greater than a density of the stepped structure 350 disposed on the first side surface 320. It may be understood that the arrangement of the dam 30 is not limited to the above examples, and other arrangements may be combined and arranged as required, and details are not described here.

It should be noted that a plurality of sharp corner structures 360 may be in a direction from the array substrate 10 to the top surface 310, and the second side surface 330 is formed by a plurality of continuously-connected sharp corner structures 360. Alternatively, the plurality of sharp corner structures 360 spaced apart from each other may be disposed on the second side surface 330. The specific design may be designed according to actual conditions, and is not specifically limited here.

The sharp corner structure 360 is formed of a third plane 361 and a fourth plane 362 intersected with each other. In some embodiments, the third plane 361 is parallel to the array substrate 10, and a projection length of the fourth plane 362 perpendicular to the array substrate 10 is smaller than a projection length of the second plane 352 perpendicular to the array substrate 10. It can be seen that, within a same length, the density of the sharp corner structures 360 is greater than the density of the stepped structure 350. Therefore, the sharp corner structure 360 having a greater density is broken when it is bent, thereby releasing stress and avoiding the stress concentration. In some other embodiments, an included angle between the third plane 361 and the fourth plane 362 is acute.

Since the sharp corner structures 360 are made of a hard material, by disposing the sharp corner structures 360 at the second side surface 330 of the dam 30 away from a light-emitting surface, the sharp corner structures 360 may be broken when the display panel is bent, thereby releasing a tip stress and avoiding the stress concentration. Further, since the sharp corner structure 360 is disposed in the non-display area, the breakage of the sharp corner structure 360 does not affect a display condition of the display panel.

In some embodiments, a microcapsule self-repairing material is disposed on the sharp corner structures 360, and the microcapsule self-repairing material coated on surfaces of the sharp corner structures 360 may be self-repaired when the sharp corner structures 360 is broken, such that the sharp corner structures 360 is reused.

In some embodiments, the connection of the second side surface 330 and the top surface 310 of the dam 30 according to any one of the above embodiments may be surrounded by two or more curved or toothed portions connected end to end. By the design of the curved portion and the toothed portion, the contact area between the ink in the encapsulation layer 20 and the dam 30 can be further increased, and thus the surface tension of the ink can be further increased, and an amount of the ink in the encapsulation layer 20 flowing beyond the dam 30 is reduced.

Further referring to FIGS. 8 and 9, FIG. 8 is a seventh structural schematic view of the dam in the flexible display panel shown in FIG. 1. FIG. 9 is an eighth structural schematic view of the dam in the flexible display panel shown in FIG. 1. In some embodiments, at least one of the first side surface 320 and the second side surface 330 is the stepped structure 350. By disposing at least one of the first side surface 320 and the second side surface 330 as the stepped structure 350, it is possible to increase the contact area between the ink in the encapsulation layer 20 and the dam 30, thereby preventing the ink from flowing beyond the dam 30.

The case that at least one of the first side surface 320 and the second side surface 330 is the stepped structure 350 and the top surface 310 is disposed without the grooves 340 may include the following. By way of example, in some embodiments, the grooves 340 or the stepped structure 350 is disposed on the first side surface 320, the second side surface 330 is disposed with the stepped structure 350, and the top surface 310 is disposed without the grooves 340. In some embodiments, the grooves 340 or the stepped structure 350 is disposed on the second side surface 330, the first side surface 320 is disposed with the stepped structure 350, and the top surface 310 is disposed without the grooves 340. In some embodiments, the first side surface 320 and the second side surface 330 of the dam 30 both are the stepped structures 350, and by disposing the first side surface 320 and the second side surface 330 both as the stepped structures 350, the contact area between the ink in the encapsulation layer 20 and the dam 30 may be increased to prevent a problem of ink overflow. In some embodiments, the first side surface 320 of the dam 30 is disposed with the stepped structure 350, and the second side surface 330 is a plurality of continuous sharp corner structures 360. By disposing the sharp corner structures 360, the contact area between the ink in the encapsulation layer 20 and the dam 30 may be increased, and the stress may be released by the breaking of the sharp corner structures 360 to avoid the problem of the stress concentration when the flexible display panel 100 is bent. In some embodiments, the first side surface 320 and the second side surface 330 of the dam 30 are both the stepped structures 350, and at least one of the first side surface 320 and the second side surface 330 is disposed with the grooves 340. By further defining the grooves 340 at the first side surface 320 and the second side surface 330 both as the stepped structures 350, the contact area between the ink in the encapsulation layer 20 and the grooves 340 may be increased due to the grooves 340, and the ink may be accommodated by the grooves 340 to further alleviate the problem of the ink overflow. In some other embodiments, the first side surface 320 of the dam 30 is the stepped structure 350, the second side surface 330 is the plurality of continuous sharp corner structures 360, and at least one of the first side surface 320 and the second side surface 330 is disposed with the grooves 340. The problem of the ink overflow is improved by the stepped structure 350 and the grooves 340, and the stress is released by using the self-breaking of the sharp corner structures 360. It may be understood that the dam 30 in embodiments of the present disclosure is not limited to the above-mentioned examples, and includes combinations of other ways. The dam 30 in embodiments of the present disclosure is not specifically limited here and may be designed according to actual conditions.

In some embodiments, a microcapsule self-repairing material 60 is disposed on the sharp corner structures 360. After the sharp corner structures 360 is broken, the microcapsule self-repairing material 60 coated on the surfaces of the sharp corner structures 360 may be self-repaired, such that the sharp corner structures 360 is reused.

In some embodiments, at least one of the top surface 310 or the side surfaces of the dam 30 according to any one of the above embodiments is covered with a hydrophobic film layer 50. The ink in the encapsulation layer 20 comes into contact with the hydrophobic film layer 50, and then the problem of the ink overflow can be effectively prevented.

The flexible display panel 100 in embodiments of the present disclosure includes a plurality of dams 30, and a distance between two adjacent dams 30 is less than 500 microns. The shape and size of each dam 30 may be set according to actual conditions, and is not specifically limited here.

In some embodiments, outer surfaces of the top surface 310 and the side surfaces of the dam 30 according to any one of the above embodiments are rough surfaces which may increase adhesion of liquid and thus reduce an overflow of the ink.

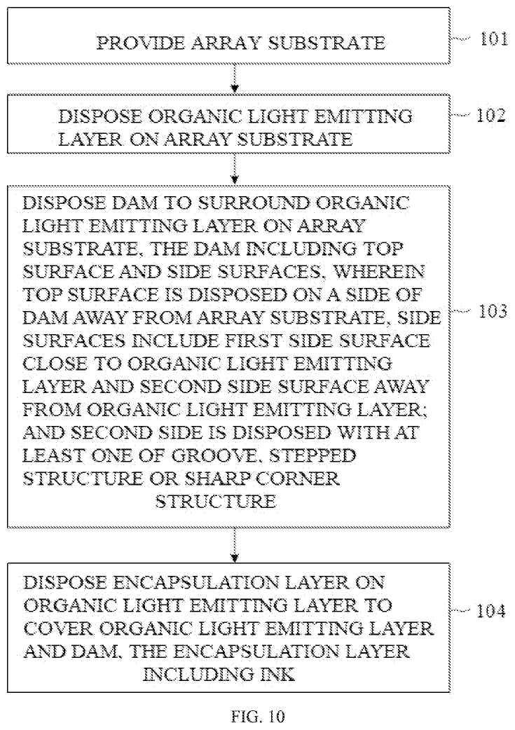

Further referring to FIG. 10, FIG. 10 is a first schematic flowchart of a manufacturing method of the flexible display panel 100 according to an embodiment of the present disclosure. An embodiment of the present disclosure further provides a manufacturing method of the flexible display panel 100. The above flexible display panel 100 is manufactured by the manufacturing method. Specific steps of the manufacturing method are as follows:

101. Provide an array substrate.

By way of example, a substrate is provided. The substrate may be a glass substrate or a flexible substrate. On the substrate, a lighting shield (LS) layer is disposed using a wet etching method.

A buffer layer is deposited on the LS using a CVD method.

An IGZO is deposited on the buffer layer using an inline sputter method.

A GI layer is deposited on the IGZO using a CVD process.

A gate layer is prepared on a GI using a wet etching method.

An ILD layer is prepared on a gate using a CVD.

An S/D is prepared on an ILD using a wet etching method.

A PV layer is prepared on the S/D using a CVD method.

A PLN layer is disposed above the PV layer.

102. An organic light emitting layer is disposed on the array substrate.

An organic light emitting layer 40 is disposed on one side of the array substrate 10 to form a display region and a non-display region.

103. A dam is disposed to surround the organic light emitting layer on the array substrate. The dam includes a top surface and side surfaces. The top surface is disposed on a side of the dam away from the array substrate. The side surfaces include a first side surface close to the organic light emitting layer and a second side surface away from the organic light emitting layer. The second side is disposed with at least one of a groove, a stepped structure, or a sharp corner structure.

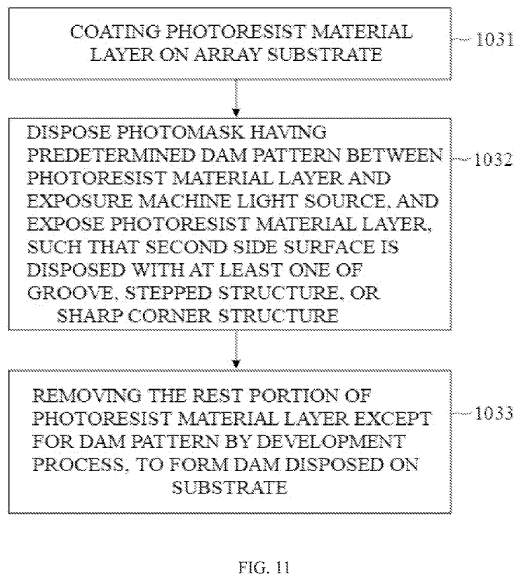

The dam 30 is disposed to surround the organic light emitting layer 40 on the array substrate 10. A material of the dam 30 includes, but is not limited to, polyimide. Specific arrangement of the dam 30 may be shown in FIG. 11. FIG. 11 is a schematic flowchart of manufacturing the dam 30 in the manufacturing method described in FIG. 10. Specific process steps are as follows:

1031. A photoresist material layer is coated to the array substrate.

A photoresist material is coated on the array substrate 10 to form a photoresist material layer, wherein the photoresist material layer may form a material having a hydrophobic property after high exposure.

1032. A photomask having a predetermined dam pattern is disposed between the photoresist material layer and an exposure machine light source, and the photoresist material layer is exposed, such that at least one of a groove, a stepped structure, or a sharp corner structure is disposed at the second side surface.

By exposing the photoresist material layer, a pattern of the dam 30 in any one of the above embodiments may be exposed. By way of example, a predetermined pattern of the dam 30 may be that at least two of the top surface 310, the first side surface 320, and the second side surface 330 of the dam 30 are disposed with grooves 340. The predetermined pattern of the dam 30 may be disposed according to actual conditions, and is not specifically limited here.

1033. A portion of the photoresist material layer except for the dam pattern is removed by a development process, to form the dam disposed on the substrate.

The portion of the photoresist material layer except for the dam pattern is removed by a development process, to form the dam 30 disposed on the array substrate 10.

The dam 30 is obtained by a coating process, an exposure process, and a development process. At least two of the top surface 310, the first side surface 320, and the second side surface 330 of the dam 30 are disposed with the grooves 340. A contact area between the dam 30 and ink in an encapsulation layer 20 may be increased through the grooves 340, and the grooves 340 may carry the ink to further prevent the ink from flowing beyond the dam 30. In addition, when the flexible display panel 100 is bent, the grooves 340 disposed at the dam 30 can avoid the case where the flexible display panel 100 is broken due to the stress concentration, thereby increasing the lifespan of the flexible display panel 100.

In some embodiments, the photoresist material layer is subjected to a high exposure so that a hydrophobic film layer 50 is formed on at least one of the top surface 310, the first side surface 320, and the second side surface 330 of the dam 30. The overflow of the ink in the encapsulation layer 20 can be effectively prevented by the hydrophobic film layer 50.

104. An encapsulation layer is disposed on the organic light emitting layer to cover the organic light emitting layer and the dam. The encapsulation layer includes ink.

The encapsulation layer 20 is disposed on an organic layer, and the organic light emitting layer 40 and the dam 30 are encapsulated by the encapsulation layer 20 so as to prevent impurities such as moisture and the like from penetrating into the flexible display panel 100.

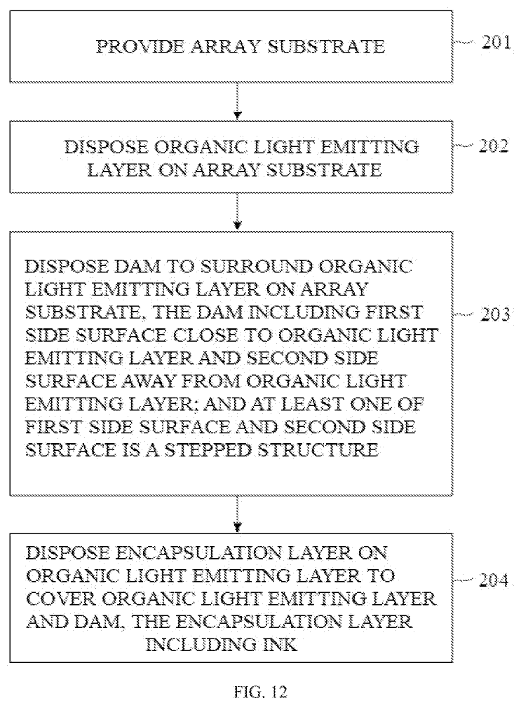

Further referring to FIG. 12, FIG. 12 is a second schematic flowchart of a manufacturing method of a flexible display panel 100 according to an embodiment of the present disclosure. An embodiment of the present disclosure further provides a manufacturing method of the flexible display panel 100. The flexible display panel 100 is provided by the manufacturing method. Specific steps of the manufacturing method are as follows:

201. Provide an array substrate.

For details, please refer to step 101 above, and the details are not described here.

202. An organic light emitting layer is disposed on the array substrate.

For details, please refer to step 102 above, and the details are not described here.

203. A dam is disposed to surround the organic light emitting layer on the array substrate. The dam includes a first side surface close to the organic light emitting layer and a second side surface away from the organic light emitting layer. At least one of the first side surface and the second side surface is a stepped structure.

A dam 30 is obtained by a coating process, an exposure process, and a development process on the array substrate 10. At least one of a first side surface 320 and a second side surface 330 of the dam 30 is a stepped structure 350.

204. An encapsulation layer is disposed on the organic light emitting layer to cover the organic light emitting layer and the dam. The encapsulation layer includes ink.

For details, please refer to step 104 above.

In embodiments of the present disclosure, the dam 30 is disposed on the array substrate 10, and by disposing at least one of the first side surface 320 and the second side surface 330 of the dam 30 as the stepped structure 350, a contact area between the ink in the encapsulation layer 20 and the dam 30 can be increased, such that surface tension of the ink can be increased, and a problem of the overflow of the ink in the encapsulation layer 20 can be improved.

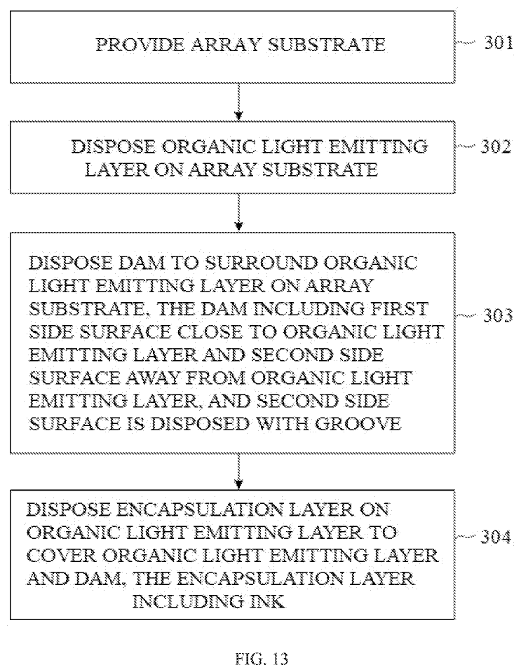

Please continue referring to FIG. 13, FIG. 13 is a third schematic flowchart of a manufacturing method of the flexible display panel 100 according to an embodiment of the present disclosure. An embodiment of the present disclosure further provides a manufacturing method of the flexible display panel 100. The above flexible display panel 100 is manufactured by the manufacturing method. Specific steps of the manufacturing method are as follows:

301. Provide an array substrate.

For details, please refer to step 101 above, and details are not described herein.

302. An organic light emitting layer is disposed on the array substrate.

For details, please refer to step 102 above, and details are not described herein.

303. A dam is disposed to surround the organic light emitting layer on the array substrate. The dam includes a first side surface close to the organic light emitting layer and a second side surface away from the organic light emitting layer, and the second side surface is disposed with a groove.

A dam 30 is obtained by a coating process, an exposure process, and a development process. Grooves 340 are defined on the second side surface 330 of the dam 30.

304. An encapsulation layer is disposed on the organic light emitting layer to cover the organic light emitting layer and the dam. The encapsulation layer includes ink.

For details, please refer to step 104 above.

In embodiments of the present disclosure, the dam 30 is disposed on the array substrate 10, and by defining the grooves 340 on the second side surface 330 of the dam 30, a contact area between the ink in the encapsulation layer 20 and the dam 30 can be increased, such that surface tension of the ink can be increased, and a problem of the overflow of the ink in the encapsulation layer 20 can be improved.

The flexible display panel provided in embodiments of the present disclosure and the manufacturing method thereof are described in detail above. The principles and embodiments of the present disclosure are described herein by using specific examples. The description of the foregoing embodiments is merely intended to help understand the present disclosure. At the same time, those skilled in the art may have changes in the specific embodiments and application scope according to the idea of the present disclosure. In summary, the content of the writing description should not be construed as a limitation to the present disclosure.

What is claimed is:

1. A flexible display panel, wherein the flexible display panel comprises:
an array substrate;
an organic light emitting layer, wherein the organic light emitting layer is disposed on the array substrate;
a dam, wherein the dam is disposed on the array substrate and disposed to surround the organic light emitting layer;
an encapsulation layer, wherein the encapsulation layer covers the organic light emitting layer and the dam, and the encapsulation layer comprises ink;
wherein the dam comprises a top surface away from the array substrate, a first side surface close to the organic light emitting layer, and a second side surface away from the organic light emitting layer, and the second side surface is disposed with at least one of a groove, a stepped structure, or a sharp corner structure.

2. The flexible display panel according to claim 1, wherein at least one of the top surface and the first side surface is disposed with the groove.

3. The flexible display panel according to claim 1, wherein the first side surface is disposed with the stepped structure.

4. The flexible display panel according to claim 1, wherein the groove is disposed on the stepped structure.

5. The flexible display panel according to claim 3, wherein when the sharp corner structure is disposed on the second side surface, a density of the sharp corner structure disposed on the second side surface is greater than a density of the stepped structure disposed on the first side surface.

6. The flexible display panel according to claim 1, wherein a microcapsule self-repairing film layer is disposed on the sharp corner structure.

7. The flexible display panel according to claim 1, wherein the flexible display panel further comprises:
a hydrophobic film layer, wherein the hydrophobic film layer covers at least one of the top surface, the first side surface, and the second side surface of the dam.

8. The flexible display panel according to claim 1, wherein a cross-sectional shape of the groove is one of a rectangular shape, a trapezoidal shape, a triangular shape, a V-shaped shape, an arc shape, or a semi-elliptical shape.

9. The flexible display panel according to claim 1, wherein the display panel comprises a plurality of dams, and a distance between adjacent two of the dams is less than 500 microns.

10. The flexible display panel according to claim 1, wherein the top surface and the side surfaces of the dam are rough surfaces.

11. A manufacturing method of a flexible display panel, wherein the manufacturing method comprises:
providing an array substrate;
disposing an organic light emitting layer on the array substrate;
disposing a dam to surround the organic light emitting layer on the array substrate, the dam comprising a top surface and side surfaces, wherein the top surface is disposed on a side of the dam away from the array substrate, the side surfaces comprising a first side surface close to the organic light emitting layer and a second side surface away from the organic light emitting layer; and the second side surface is disposed with at least one of a groove, a stepped structure, or a sharp corner structure;
disposing an encapsulation layer on the organic light emitting layer to cover the organic light emitting layer and the dam, wherein the encapsulation layer comprises ink.

12. The manufacturing method according to claim 11, wherein the disposing the dam to surround the organic light emitting layer on the array substrate comprises:
coating a photoresist material layer on the array substrate;
disposing a photomask having a predetermined dam pattern between the photoresist material layer and an exposure machine light source, and exposing the photoresist material layer such that the second side surface is disposed with at least one of the groove, the stepped structure, or the sharp corner structure;
removing a portion of the photoresist material layer except for the dam pattern by a development process to form the dam disposed on the substrate.

13. The manufacturing method according to claim 12, wherein the photoresist material layer is subjected to a high exposure so that a hydrophobic film layer is formed on at least one of the top surface, the first side surface, and the second side surface of the dam.

14. The manufacturing method according to claim 11, wherein at least one of the top surface and the first side surface is disposed with a groove.

15. The manufacturing method according to claim 11, wherein the first side surface is disposed with the stepped structure.

16. The manufacturing method according to claim 11, wherein a groove is disposed on the stepped structure.

17. The manufacturing method according to claim 15, wherein when the sharp corner structure is disposed on the second side surface, a density of the sharp corner structure disposed on the second side surface is greater than a density of the stepped structure disposed on the first side surface.

18. The manufacturing method according to claim 11, wherein a cross-sectional shape of the groove is one of a rectangular shape, a trapezoidal shape, a triangular shape, a V-shaped shape, an arc shape, or a semi-elliptical shape.

19. The manufacturing method according to claim 11, wherein the manufacturing method further comprises:
disposing a plurality of the dams on the array substrate, wherein a distance between adjacent two of the dams is less than 500 microns.

20. The manufacturing method according to claim 11, wherein the top surface and the side surfaces of the dam are rough surfaces.
